(19) United States
(12) Patent Application Publication
(10) Pub. No.: US 2008/0290513 A1
(43) Pub. Date: Nov. 27, 2008

(54) SEMICONDUCTOR PACKAGE HAVING MOLDED BALLS AND METHOD OF MANUFACTURING THE SAME

(75) Inventors: Hyung-Jik BYUN, Gyeonggi-do (KR); Jong-Gi LEE, Gyeonggi-do (KR); Jong-Ho LEE, Chungcheongnam-do (KR); Se-Young YANG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/125,391

(22) Filed: May 22, 2008

(30) Foreign Application Priority Data
May 22, 2007 (KR) 2007-0049941

(51) Int. Cl. H01L 23/488

(52) U.S. Cl. 257/738; 257/783; 257/E23.023

(57) ABSTRACT

Provided are a semiconductor package having molded balls on a bottom surface of a PCB and a method of manufacturing the semiconductor package. The semiconductor package includes: a semiconductor chip mounting member comprising circuit patterns on a first surface, an insulating layer defining openings exposing at least portions of the circuit patterns, and external contact terminals arranged on the portions of circuit patterns exposed by the openings; a semiconductor chip formed on a second surface of the semiconductor chip mounting member and electrically connected to the semiconductor chip mounting member; a first sealing portion coating the second surface of the semiconductor chip mounting member and the semiconductor chip; and a second sealing portion arranged on the insulating layer and the external contact terminals such that at least portions of the external contact terminals are exposed.

### CROSS-REFERENCE TO RELATED PATENT APPLICATION

This application claims priority under 35 USC § 119 to Korean Patent Application No. 10-2007-0049941, filed on May 22, 2007 in the Korean Intellectual Property Office, the disclosure of which is incorporated herein in its entirety by reference.

### BACKGROUND

1. Technical Field

The present invention relates to a semiconductor package, and more particularly, to a semiconductor package having molded balls on a bottom surface of a PCB, and a method of manufacturing of the same.

2. Description of the Related Art

With the rapid development of digital communications, smaller and more functional electronic appliances, such as portable PCs or mobile phones, are increasingly in demand. Accordingly, semiconductor products used in such electronic appliances should be small, light, and have higher capacity. Thus, much attention has been paid to a ball grid array (BGA) package. Unlike a conventional lead frame package in which leads used as external contact terminals are arranged one-dimensionally around a chip, the BGA package includes solder balls that are used as external contact terminals on a bottom surface of a semiconductor package, and thus the external contact terminals can be arranged more efficiently.

FIGS. 1A and 1B are cross-sectional views of a conventional semiconductor package 100, wherein one external contact terminal is illustrated. FIGS. 2A and 2B are photographs showing problems caused in the conventional semiconductor packages of FIGS. 1A and 1B. Referring to FIGS. 1A and 1B, the semiconductor package 100 includes a substrate 110 having a circuit pattern 120 on a side thereof. A solder mask layer 130 is formed on the substrate 110. The solder mask layer 130 is formed such that the circuit pattern 120 is completely exposed or a portion of the circuit pattern 120 is exposed. A solder ball 140 is formed on the exposed circuit pattern 120 using a surface mounting method. A semiconductor chip (not shown) is mounted on the other side of the substrate 110.

However, when the conventional semiconductor package 100 including the solder ball is mounted on a package mounting substrate, a crack 150a can be generated in an open area of the solder mask layer 130, thereby causing a crack of a circuit wiring 125 arranged inside the substrate 110 as illustrated in FIG. 2A. Also, a crack 150b can be generated in the solder ball 140 as illustrated in FIG. 2B. This happens because stress is concentrated on the solder ball 140 due to the mismatch between the coefficients of thermal expansion of the semiconductor package and the package mounting substrate. Also, during a package-on-package (POP) bending or dropping test, mechanical stress between the semiconductor package and the package mounting substrate can cause a crack in the solder ball, which decreases the reliability of the semiconductor package.

### SUMMARY

The present invention provides a semiconductor package having molded external contact terminals arranged on a semiconductor chip mounting substrate, and a method of manufacturing the semiconductor package.

According to an aspect of the present invention, there is provided a semiconductor package comprising: a semiconductor chip mounting member comprising circuit patterns on a first surface, an insulating layer defining openings exposing at least portions of the circuit patterns, and external contact terminals arranged on the portions of circuit patterns exposed by the openings; a semiconductor chip formed on a second surface of the semiconductor chip mounting member and electrically connected to the semiconductor chip mounting member; a first sealing portion coating the second surface of the semiconductor chip mounting member and the semiconductor chip; and a second sealing portion arranged on the insulating layer and the external contact terminals such that at least portions of the external contact terminals are exposed.

### BRIEF DESCRIPTION OF THE DRAWINGS

The above and other features and advantages of the present invention will become more apparent by describing in detail exemplary embodiments thereof with reference to the attached drawings in which:

FIG. 1A is a cross-sectional view of a conventional semiconductor package;

FIG. 1B is a cross-sectional view of another conventional semiconductor package;

FIGS. 2A and 2B are photographs showing problems caused in the conventional semiconductor packages of FIGS. 1A and 1B;

FIG. 3A is a cross-sectional view of a semiconductor package according to an embodiment of the present invention;

FIG. 3B is a cross-sectional view of a semiconductor package according to another embodiment of the present invention;

FIG. 4 is a flowchart of a method of manufacturing a semiconductor package according to an embodiment of the present invention;

FIG. 5A is a plan view illustrating the method of manufacturing the semiconductor package of FIG. 3A, according to an embodiment of the present invention;

FIGS. 5B through 5I are cross-sectional views illustrating the method of manufacturing the semiconductor package of FIG. 3A, according to an embodiment of the present invention; and

FIGS. 6A through 6D are cross-sectional views illustrating the method of manufacturing the semiconductor package of FIG. 3A, according to another embodiment of the present invention.

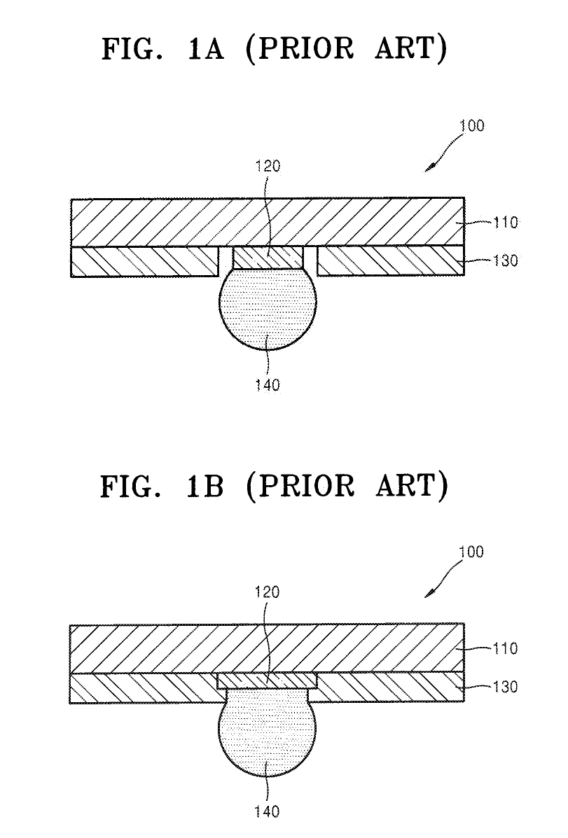

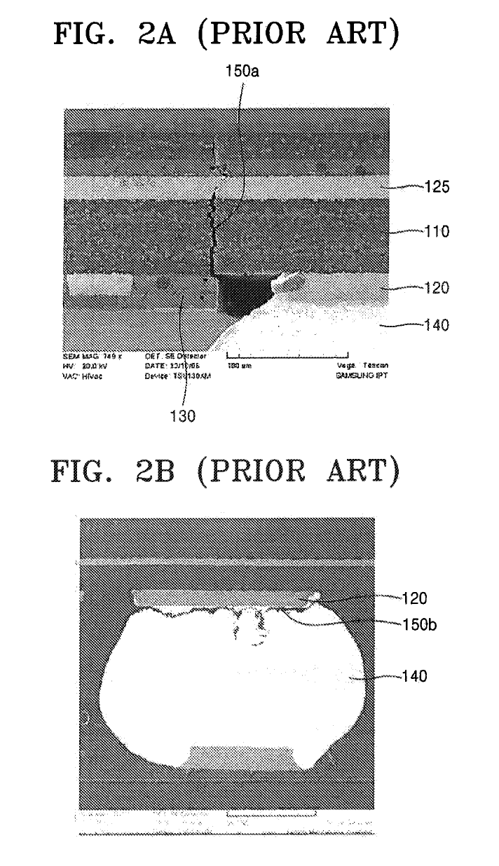

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Accordingly, the shapes of elements in the drawings are exaggerated for clarity, and like reference numerals in the drawings denote like elements, and thus their description will be omitted.

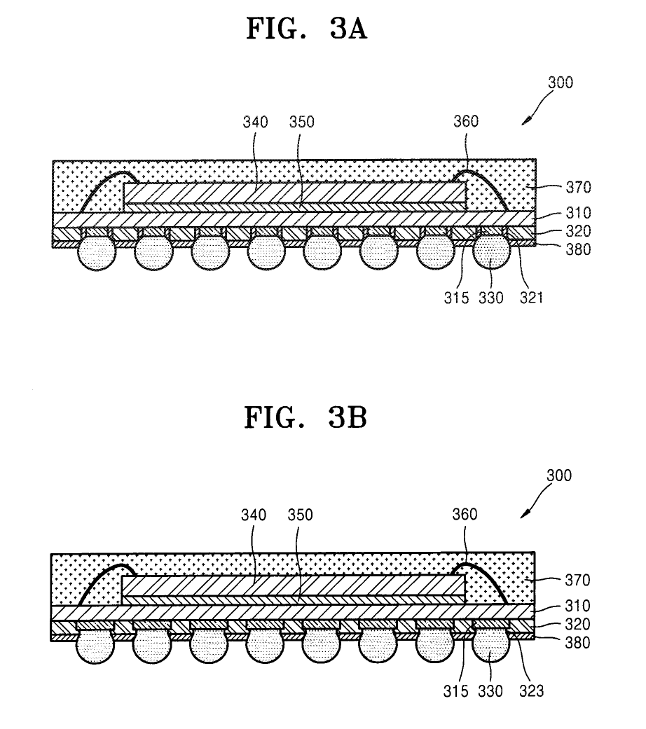

FIGS. 3A and 3B are cross-sectional views of a semiconductor package 300 according to an embodiment of the present invention. Referring to FIGS. 3A and 3B, the semiconductor package 300 includes a substrate 310 and a semiconductor chip 340 mounted on the substrate 310. The substrate 310 may include a printed circuit board (PCB). The substrate 310 may be a tape substrate. The semiconductor chip 340 is mounted on an upper surface of the substrate 310 using an adhesive 350, and pads of the semiconductor chip 340 are electrically connected via wires 360 to circuit patterns (not shown) arranged on the upper surface of the substrate 310.

A plurality of circuit patterns 315 are formed on a lower surface of the substrate 310, and external contact terminals 330 are arranged on the circuit patterns 315. The external contact terminals 330 may include solder balls. The substrate 310 may further include circuit wirings (not shown) to electrically connect the circuit patterns arranged on the upper surface to the circuit patterns 315 arranged on the lower surface. An insulating layer 320 is formed on the lower surface of the substrate 310. The insulating layer 320 functions as a solder mask layer when external contact terminals 330 are formed. The insulating layer 320 may include a photo solder resist (PSR). The insulating layer 320 may include openings 321 or 323 exposing at least portions of the circuit patterns 315. The openings 321 may expose upper surfaces or lateral surfaces of the circuit patterns 315 and the openings 323 may expose portions of the upper surfaces of the circuit patterns 315.

A first sealing portion, or encapsulant, 370 is formed on the upper surface of the substrate 310 to coat the semiconductor chip 340 and the wires 360. The first sealing portion 370 may include an epoxy molding compound. A second sealing portion, or encapsulant, 380 is formed on the lower surface of the substrate 310 to partially surround the external contact terminals 330. The second sealing portion 380 may include epoxy molding compound. The second sealing portion 380 can be formed such that a portion of the external contact terminals 330 are exposed so that the second sealing portion 380 and a package mounting substrate (not shown), such as a mother board, can be electrically connected. The thickness of the second sealing portion 380 may be about half or less of the height of the external contact terminals. The second sealing portion 380 may substantially surround a portion of the external contact terminals 330 in order to mitigate stress applied to the external contact terminals. In particular, the second sealing portion 380 can be completely buried in the openings 321, as illustrated in FIG. 3A, thereby surrounding a portion of the external contact terminals 330 and mitigating stress. More specifically, the second sealing portion 380 substantially surrounds a portion of the external contact terminals 330 that is in the vicinity of where the external contact terminals 330 contact the circuit patterns 315. Thus, the second sealing portion 380 adds mechanical stability to the connection between the circuit patterns 315 and the external contact terminals 330.

The semiconductor chip 340 may also be electrically connected to the substrate 310 by arranging connection terminals, or solder balls, on the semiconductor chip 340, rather than via the wires 360. Also, the semiconductor package 300 may have a multi-chip package (MCP) structure or a package-on-package (POP) structure.

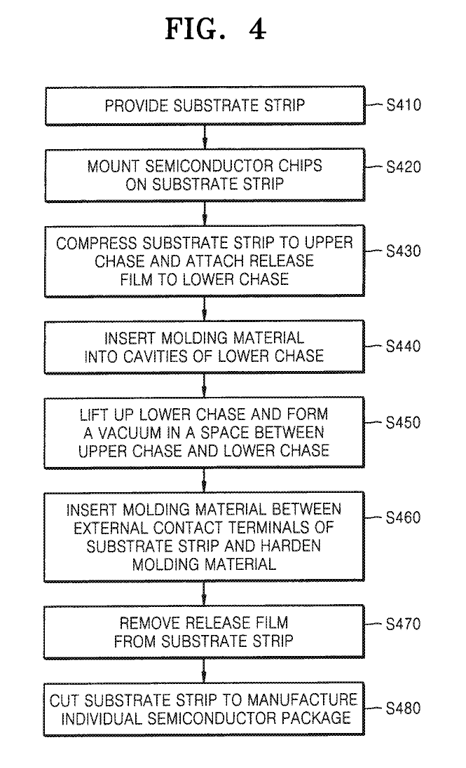

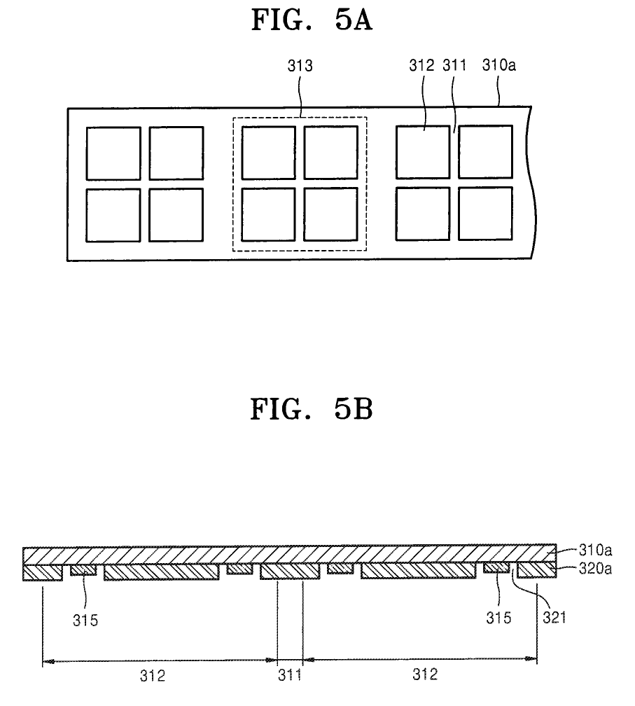

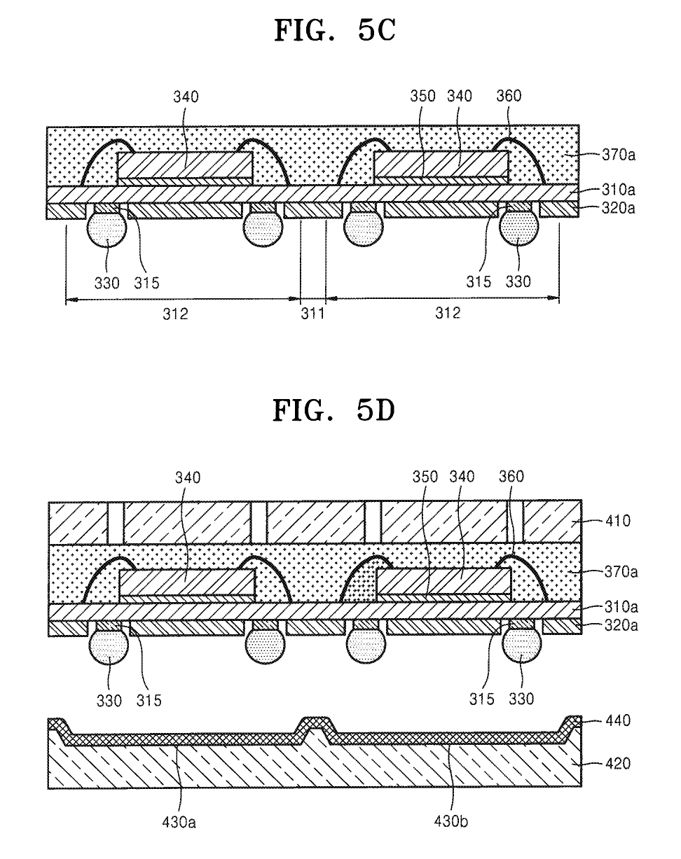

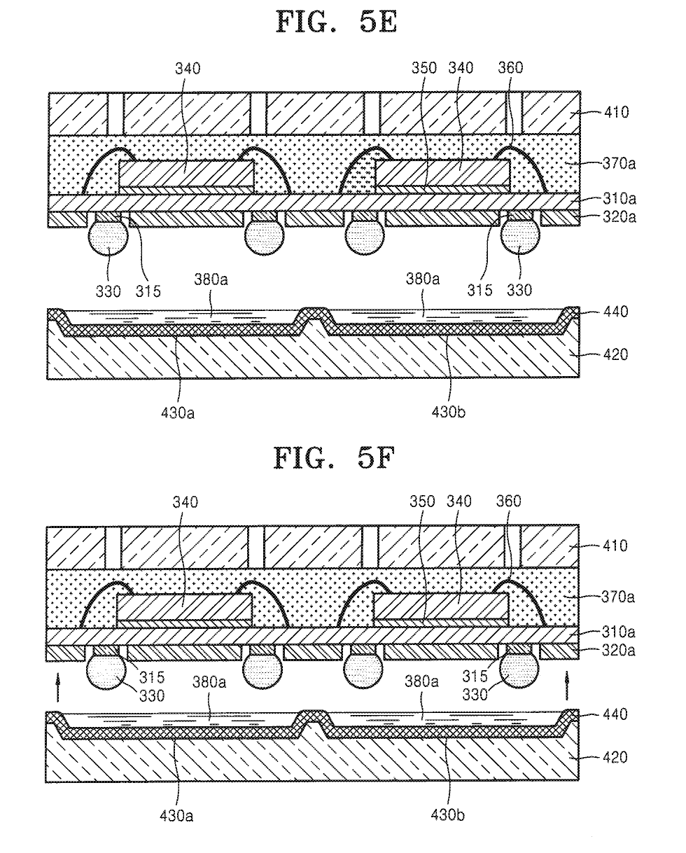

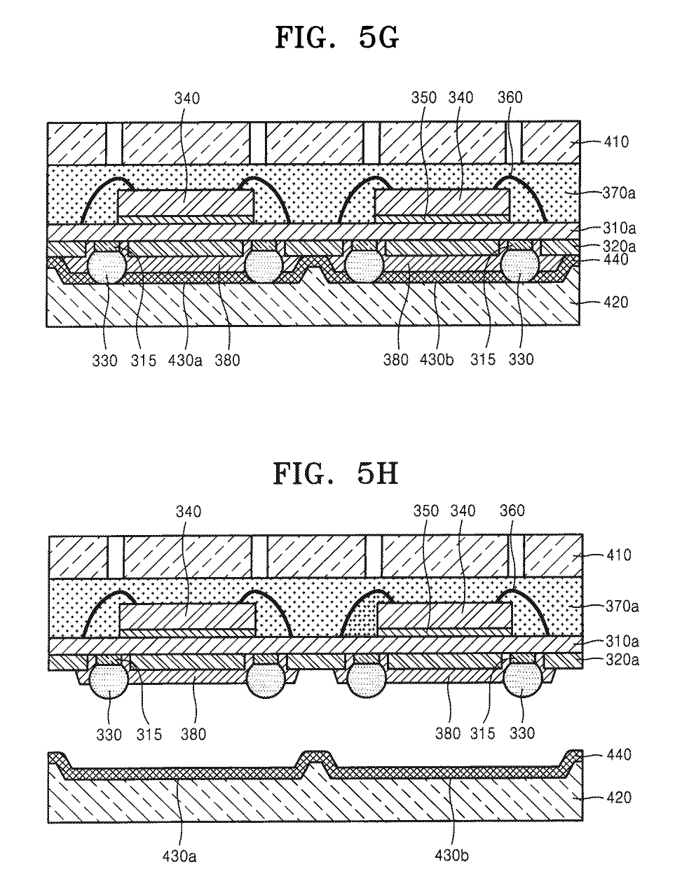

FIG. 4 is a flowchart of a method of manufacturing a semiconductor package according to an embodiment of the present invention. FIG. 5A is a plan view illustrating the method of manufacturing the semiconductor package shown in FIG. 3A, and FIGS. 5B through 5I are cross-sectional views illustrating the method of manufacturing the semiconductor package shown in FIG. 3A.

Referring to FIGS. 4, 5A, and 5B, first, a substrate strip 310a is provided in operation S410. The substrate strip 310a may be a PCB strip or a tape strip. The substrate strip 310a includes a plurality of unit molding areas 313. At least one unit substrate area 312 is arranged in each of the unit molding areas 313. The unit substrate area 312, whereon a unit semiconductor chip is arranged, is cut in a subsequent strip cutting process along a scribing area 311 to become the substrate 310 of the semiconductor package substrate (300 in FIG. 3A).

A plurality of circuit patterns (not shown) are arranged on each of the unit substrate areas 312 of an upper surface of the substrate strip 310a to connect with the unit semiconductor chips (340 in FIG. 3A), and circuit patterns 315 are arranged on each of the unit substrate areas 312 of a lower surface to connect to an outside device. An insulating layer 320a is formed on the circuit patterns 315 and the lower surface of the substrate strip 310a. The insulating layer 320a includes openings 321 exposing the circuit patterns 315. The substrate strip 310a may further include circuit wirings (not shown) which are arranged in the unit substrate area 312 to electrically connect the circuit patterns 315 arranged on the lower surface and the circuit patterns arranged on the upper surface.

Referring to FIGS. 4 and 5C, unit semiconductor chips 340 are respectively mounted on the unit substrate areas 312 in operation S420. The unit semiconductor chips 340 can be manufactured in a general semiconductor manufacturing process and attached to the unit substrate areas 312 using an adhesive 350. A plurality of pads (not shown) may be arranged on a surface of the unit semiconductor chip 340. The unit semiconductor chip 340 may include a single semiconductor chip or a stack of semiconductor chips.

The pads of the semiconductor chips 340 and the circuit patterns arranged on each of the unit substrate areas 312 on the upper surface of the substrate strip 310a can be electrically connected by the wires 360. The semiconductor chips 340 and the wires 360 of the substrate strip 310a are then molded using a molding, or encapsulation, process. The molding process is performed for each unit molding area 313 and the unit semiconductor chips 340 arranged on each of the unit molding areas 313 are molded at the same time and coated by a first common sealing portion 370a. The first common sealing portion 370a may include an epoxy molding compound.

A plurality of external contact terminals 330 are arranged on the circuit patterns 315 disposed on the lower surface of the substrate strip 310a to connect the circuit patterns 315 to an outside device. The external contact terminals 330 may include solder balls. The insulating layer 320a may include photo solder resist.

Referring to FIGS. 4 and 5D, a semiconductor package molding device including an upper chase 410 and a lower chase 420 is provided. The lower chase 420 includes one or more cavities 430a and 430b. The cavities 430a and 430b are arranged corresponding to each of the unit substrate areas 312 arranged on the unit molding area 313. The cavities 340a and 340b may have a size capable of including all of the external contact terminals 330 corresponding to each of the semiconductor chips 340 arranged in the unit substrate area 312.

The substrate strip 310a is adhered to the upper chase 410 and a release film 440 is attached to the lower chase 420 in operation S430. The upper surface of the first common sealing portion 370a of the substrate strip 310a is adhered to the upper chase 410. The release film 440 may preferably have a sufficient thickness such that the external contact terminals 330 of the substrate strip 310a can be inserted in the release film 440 when the upper and lower chases 410 and 420 are compressed. The release film 440 may have a thickness corresponding to the portion of the external contact terminals 330 not surrounded by the second sealing portion (380 in FIG. 5I) in a subsequent process and a height about half or greater of the height of the external contact terminals 330.

Referring to FIGS. 4 and 5E, a molding material 380a is inserted on the release film 440 into the cavities 430a and 430b of the lower chase 420 in operation S440. The molding material 380a may be of a liquid type, a granule type, or a powder type. The molding material 380a may include an epoxy molding compound.

Referring to FIGS. 4, 5F, and 5G, the lower chase 420 is lifted into contact with the substrate strip 310a and a vacuum state is formed in the space between the upper chase 410 and the lower chase 420 in operation S450. The lower chase 420 is further lifted to compress against the upper chase 410. A portion of the external contact terminals 330 is inserted into the release film 440 and thus the molding material 380a is buried in the openings 321.

Next, the molding material 380a is hardened to form second sealing portions 380 in operation S460. The molding material 380a can be hardened by a heat treatment step. The second sealing portions 380 are respectively formed corresponding to the semiconductor chip 340 of the unit substrate area 312 so as to substantially surround portions of the external contact terminals 330 arranged in each of the unit substrate areas 312. The thickness of the second sealing portions 380 is determined according to the thickness of the release film 440 and the depth of the cavities 430a and 430b, and the second sealing portions 380 may be formed to surround portions of the external contact terminals 330 to about half of the height of the external contact terminals 330 or less.

Referring to FIGS. 4, 5H, and 5I, the release film 440 is separated from the substrate strip 310a in operation S470. The lower chase 420 is lowered and thus separated from the upper chase 410, and the vacuum in the space between the upper chase 410 and the lower chase 420 is released. The substrate strip 310a is separated from the upper chase 410.

Then, the substrate strip 310a is cut along the scribing area 311 using a blade or the like to manufacture an individual semiconductor package 300. The first common sealing portion 370a is cut using a cutting process and thus becomes the first sealing portion 370 sealing the semiconductor chip 340 of the semiconductor package 300.

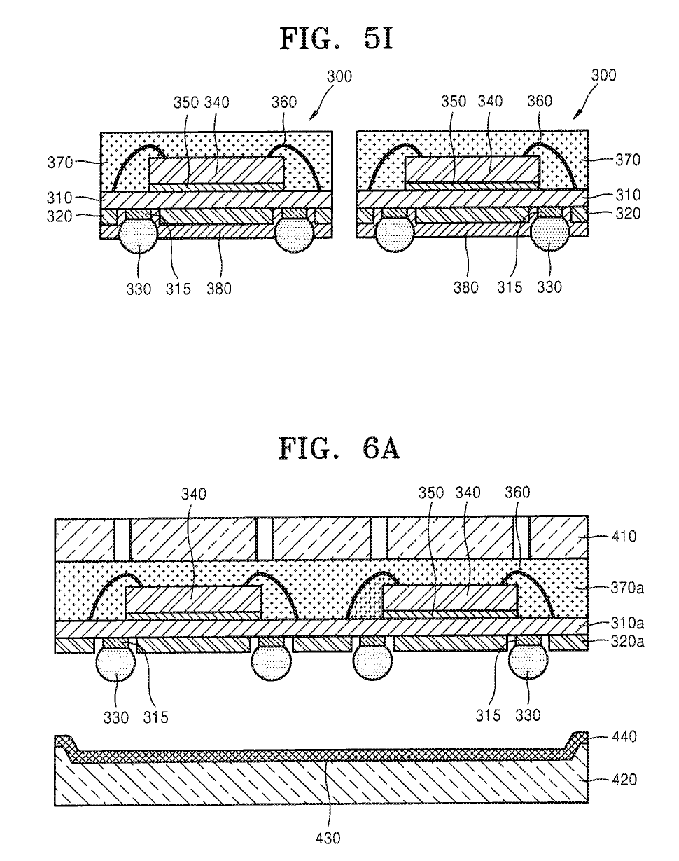

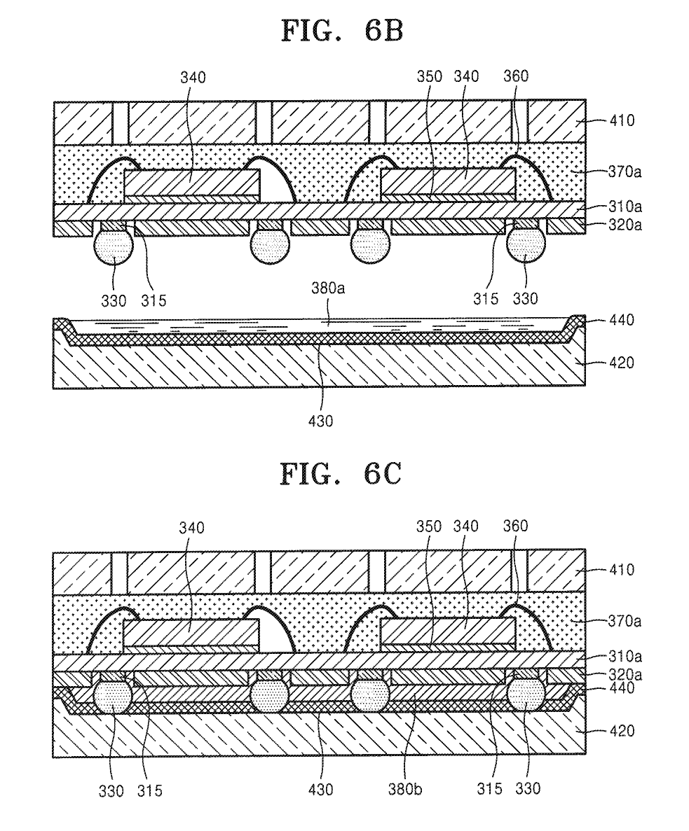

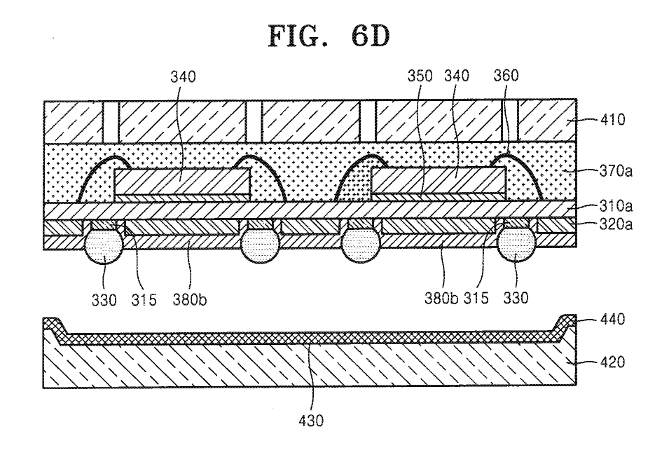

FIGS. 6A through 6D are cross-sectional views of a method of manufacturing the semiconductor package of FIG. 3A, according to another embodiment of the present invention. This method is similar to the method of the previous embodiment except that the second sealing portion is formed so as to seal the semiconductor chips in the unit sealing area 313 in combination, rather than separately.

First, as illustrated in FIGS. 4, 5A, and 5B, a substrate strip 310a is provided in operation S410, and a semiconductor chip 340 is mounted on each of the unit substrate area 312 on the upper surface of the substrate strip 310a as illustrated in FIG. 5C in operation S420. Then, as illustrated in FIG. 5D, a molding device including an upper chase 410 and a lower chase 420 is provided. The lower chase 420 includes a cavity 430 corresponding to the unit molding area 313 of the substrate strip 310a.

Referring to FIGS. 4 and 6A, the substrate strip 310a is adhered to the upper chase 410 of the molding device and the release film 440 is attached to the lower chase 420 in operation S430. The cavity 430 in the lower chase 420 may have a size capable of accommodating all of the external contact terminals 330 of a plurality of semiconductor chips 340, for example, of four semiconductor chips, which are arranged on the unit molding area 313.

Referring to FIGS. 4 and 6B and 6C, a molding material 380a is inserted into the cavity 430 of the lower chase 420 in operation S440. Then, the lower chase 420 is lifted and a vacuum state is formed in the space between the upper chase 410 and the lower chase 420 in operation S450. The lower chase 420 is compressed against the upper chase 410 so as to bury the molding material 380a within the opening 321. Then, by hardening the molding material 380a, a second common sealing portion 380b is formed in operation S460. The second common sealing portion 380b is arranged, like the first common sealing portion 370a, corresponding to the unit sealing area 313 and formed to surround the external contact terminals 330 of the semiconductor chips 340 arranged in the unit sealing area 313.

Referring to FIGS. 4 and 6D, the release film 440 is removed from the second common sealing portion 380b in operation S470. The lower chase 420 is lowered to separate the lower chase 420 from the upper chase 410, and the vacuum in the space between the upper chase 410 and the lower chase 420 is released. Then, the substrate strip 310a is cut along the scribing area 311 to manufacture an individual semiconductor package 300. Here, the first common sealing portion 370a is cut and becomes the first sealing portion 370 of the semiconductor package 300, and the second common sealing portion 380b is cut and becomes the second sealing portion 380 of the semiconductor package 300.

The semiconductor package 300 illustrated in FIG. 3B can also be manufactured according to the method illustrated in FIGS. 4, 5A through 5I or FIGS. 6A through 6D.

As described above, according to the semiconductor package and the method of manufacturing the semiconductor package of the present invention, the external contact terminals are arranged on the circuit patterns disposed on the semiconductor chip mounting substrate and then a molding resin is deposited on a bottom surface of the substrate so as to partially surround the external contact terminals using a molding process. Thus, cracks and open defects of the circuit wirings can be prevented, thereby improving the reliability of the semiconductor device. Also, as the molding resin is deposited on the bottom surface of the substrate strip and then an individual semiconductor package is manufactured by a cutting process, the occurrence of cracks and open defects can be minimized, the process can be simplified, and the process time can be reduced. Further, as the bottom surface of the package is coated using the molding resin, an undesirable water absorption channel is blocked and bending phenomenon of the semiconductor package can be minimized, thereby improving the reliability of the semiconductor package.

According to an aspect of the present invention, there is provided a semiconductor package comprising: a semiconductor chip mounting member including circuit patterns on a first surface, an insulating layer defining openings exposing at least portions of the circuit patterns, and external contact terminals arranged on the portions of circuit patterns exposed by the openings; a semiconductor chip disposed on a second surface of the semiconductor chip mounting member and electrically connected to the semiconductor chip mounting member; a first sealing portion coating the second surface of the semiconductor chip mounting member and the semiconductor chip; and a second sealing portion arranged on the insulating layer and the external contact terminals such that at least portions of the external contact terminals are exposed.

The first and second sealing portions may comprise an epoxy resin. The openings may be disposed such that upper surfaces and lateral surfaces of the circuit patterns are exposed or portions of the upper surfaces of the circuit patterns are exposed.

The semiconductor chip mounting member may comprise a PCB or a tape substrate. The external contact terminals may comprise solder balls. The insulating layer may be a photo solder resist.

According to another aspect of the present invention, there is provided a method of manufacturing semiconductor packages. First, a substrate strip is provided. The substrate strip includes unit sealing areas in which at least one or more unit substrate areas defined by a scribe area are arranged. Circuit patterns are arranged on a first surface of the substrate strip. An insulating layer including openings exposing at least portions of the circuit patterns is formed on the first surface of the substrate strip. Next, each of semiconductor chips is mounted on the unit substrate areas on a second surface of the substrate strip to coat the semiconductor chips of each unit sealing area as a first common sealing portion, and external contact terminals are arranged on the circuit patterns of the substrate strip. A molding device including an upper chase and a lower chase including at least one or more cavities is provided. The substrate strip is adhered on the upper chase such that the upper chase and the first common sealing portion contact each other. A molding material is inserted into the at least one or more cavities. The upper chase and the lower chase are compressed so that the molding material except portions of the external contact terminals surrounds the external contact terminals. The molding material is hardened. The substrate strip is separated from the upper chase. The substrate strip and the first common sealing portion are cut along the scribe area per unit substrate area to manufacture individual semiconductor packages.

Adhering the substrate strip to the upper chase may further comprise adhering a release film on the lower chase including the cavities. When compressing the upper and lower chases, the portions of the external contact terminals may be inserted into the release film. The cavities may be formed in the lower chase to correspond to each of the unit substrate areas of the unit sealing area. The molding material may be inserted respectively into the cavities and second sealing portions may be formed to correspond to semiconductor chips while hardening the molding material, wherein each of the second sealing portions is formed to surround the external contact terminals arranged in each of the unit substrate areas.

The cavity may be formed in the lower chase to correspond to the unit sealing area. The molding material may be inserted into the cavity and a second common sealing portion may be formed to correspond to the semiconductor chips of each of the unit sealing areas while hardening the molding material, wherein the second common sealing portion is formed to surround all of the external contact terminals arranged in each of the unit substrate areas. The second common sealing portion may be cut in the cutting process to form second sealing portions.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
a semiconductor chip mounting member including:
circuit patterns on a first surface;
an insulating layer defining openings exposing at least portions of the circuit patterns; and
external contact terminals arranged on the portions of the circuit patterns exposed by the openings;
a semiconductor chip disposed on a second surface of the semiconductor chip mounting member and electrically connected to the semiconductor chip mounting member;
a first sealing portion coating the second surface of the semiconductor chip mounting member and the semiconductor chip; and
a second sealing portion disposed on the insulating layer and the external contact terminals such that at least portions of the external contact terminals are exposed.

2. The semiconductor package of claim 1, wherein the first sealing portion comprises an epoxy resin.

3. The semiconductor package of claim 1, wherein the second sealing portion comprises an epoxy resin.

4. The semiconductor package of claim 1, wherein the openings are disposed such that upper surfaces and lateral surfaces of the circuit patterns are exposed or portions of the upper surfaces of the circuit patterns are exposed.

5. The semiconductor package of claim 1, wherein the semiconductor chip mounting member comprises a printed circuit board.

6. The semiconductor package of claim 1, wherein the semiconductor chip mounting member comprises a tape substrate.

7. The semiconductor package of claim 1, wherein the external contact terminals comprise solder balls.

8. The semiconductor package of claim 7, wherein the insulating layer is a photo solder resist.

9. A semiconductor package, comprising:
a substrate, the substrate including:
a plurality of circuit patterns disposed on a first surface of the substrate;
an insulating layer defining openings exposing at least a portion of each of the circuit patterns; and
external contact terminals disposed on the portions of the circuit patterns exposed by the openings;
a semiconductor chip disposed on a second surface of the substrate, the semiconductor chip electrically connected to the substrate;
a first encapsulant disposed on the second surface of the substrate and the semiconductor chip; and
a second encapsulant disposed on the insulating layer and the external contact terminals such that at least portions of the external contact terminals are exposed by the second encapsulant.

10. The semiconductor package of claim 9, further comprising bonding wires electrically connecting the semiconductor chip to the substrate.

11. The semiconductor package of claim 9, further comprising connection terminals electrically connecting the semiconductor chip to the substrate.

12. The semiconductor package of claim 9, wherein the second encapsulant is disposed on sidewalls of the openings defined by the insulating layer.

13. The semiconductor package of claim 9, wherein a thickness of the second encapsulant is approximately equal to half of a height of the external contact terminals above the circuit patterns.

14. The semiconductor package of claim 9, wherein a thickness of the second encapsulant is less than half of a height of the external contact terminals above the circuit patterns.

15. The semiconductor package of claim 9, further comprising an adhesive disposed between the substrate and the semiconductor chip.

16. The semiconductor package of claim 9, wherein the substrate comprises a printed circuit board.

17. The semiconductor package of claim 9, wherein the substrate comprises a tape substrate.

18. The semiconductor package of claim 9, wherein the second encapsulant comprises an epoxy resin.
